(19) United States
(12) Patent Application Publication
(10) Pub. No.: US 2010/0116322 A1
(43) Pub. Date: May 13, 2010

(54) COLLECTOR FOR THE GENERATION OF ELECTRICAL AND THERMAL ENERGY

(76) Inventors: Jörg Helbig, Altenburg (DE); Uwe Vincenz, Gössnitz (DE)

Correspondence Address: LERNER GREENBERG STEMER LLP, P O BOX 2480, HOLLYWOOD, FL, 33022-2480, US

(21) Appl. No.: 12/595,176

(22) PCT Filed: Apr. 7, 2008
(86) PCT No.: PCT/EP08/02812

§ 371 Date: Oct. 8, 2009

(30) Foreign Application Priority Data
Apr. 11, 2007 (DE) 10 2007 030 486.4

(51) Int. Cl. H01L 31/058

(52) U.S. Cl. 136/248

(57) ABSTRACT

A semitransparent collector generates electrical and thermal energy exclusively from solar radiant energy. In the collector, a semitransparent photovoltaic module that forms the top part of the collector as well as a solar thermal module which forms the bottom part of the collector and is not mechanically connected to the photovoltaic module are disposed in a common housing. An insulating space which allows thermal radiation to penetrate while preventing convective heat loss is arranged between the modules. The collector is closed in the direction of irradiation by way of a transparent support.

The invention relates to a semitransparent collector which uses radiation opaque wafers for generating electrical and thermal energy from solar radiation energy only.

Solar thermal installations are understood to be technical systems for heating heating and industrial water using solar radiation energy. These generally comprise collectors, a connecting piping system, a heat carrier medium and a storage with heat exchangers for warm water. Additionally, there are measuring, control and actuating apparatuses.

The collectors form the core of such an installation. In principle, two types of collectors are available here.

Firstly, there is the vacuum tubes collector consisting of evacuated glass tubes.

Within the tube there is a second tube or tube system which constitutes the actual absorber surface and through which the heat carrier medium flows.

The inner tube is specially coated and lies at the focal points of laterally attached mirrors. This type of collector can supply very high temperatures and has a high efficiency. However, it is very expensive and not suited to being combined with photovoltaics for structural reasons.

The second type of collector is the so-called flat collector. This type consists of a specially coated aluminum or copper foil, at the rear side of which a preferably aluminum or copper tube system is mounted in a meandering or harp-like shape.

A glass plate or similar transparent materials cover the top of this collector for protection from environmental influences.

The radiation emitted by the sun can pass through this cover with almost no attenuation. A heat carrier medium flows through the piping system mounted below the absorber surface and thus transports the heat toward the storage system. A water-glycol mixture is usually used as a heat carrier medium to prevent frost damage.

Photovoltaics refer to the direct conversion of solar radiation into electrical energy due to the liberation of charge carriers in solids.

To this end, the prior art uses semiconductors, i.e. substances which insulate near a temperature of absolute zero but become conductors at higher temperatures, due to targeted disturbance of the crystal lattice or due to the influx of external energy.

For photovoltaics to satisfy architectural needs such as visual appearance, thermal insulation, shadowing, aesthetics and glare protection, so-called semitransparent solar modules for integration into buildings (GIPV) have been available for quite some time.

These are preferably thin layer cells, particularly amorphous, polycrystalline or CIS cells.

This affords the possibility of producing PV modules with a light transmission of 1% to 99%. In particular, this means that the photovoltaic proportion can be scaled freely.

Thus, there can be facades which absorb 90% of the light at certain locations but only absorb 10% elsewhere, in which, however, all modules have the same output voltage so that they can be connected in a conventional manner.

These semitransparent cells have a multiplicity of problems. For example the stability of the cells, during production and when the perforations are inserted into the wafers, is a particular risk factor which makes series production difficult.

The problems with semitransparent cells with wafers inserted between glass plates are rather of a visual nature.

This technology only lets light pass in small regions, with the remaining regions throwing large shadows due to the type of wafer used. The use of expensive silicon wafers and the large weight because two glass plates are used are further problems.

According to the prior art, solutions are proposed which combine the known photovoltaic components with those from solar thermal technology such that heat is transferred by thermal conduction, as a result of direct contact, from the heated wafers to the solar thermal module.

This creates disadvantages in respect of the tightness of the solar thermal module connected to the electrically conductive photovoltaic module and the feedback of heat conduction from the photovoltaic module to the absorber and vice versa during changing meteorological conditions.

Furthermore, it is disadvantageous that all materials used in the combined collector have different coefficients of thermal expansion and hence there can be mechanical problems in the system.

Furthermore, the direct connection of the solar thermal collector and the semitransparent PV module is connected with high thermal losses since the heat energy is emitted by direct contact from the solar thermal absorber to the PV cells and hence to the surroundings.

It is an object of the invention to solve known problems in respect of the tightness and sealing the solar thermal collector from the photovoltaic elements in order to avoid short circuits, minimize thermal losses and rectify the known disadvantages of the prior art.

Furthermore, the drop in efficiency resulting from the combination of photovoltaics and solar thermal technology should be minimized and the mechanical problems should be resolved.

The object according to the invention is achieved by the characterizing features of claim 1 in combination with the features of the preamble. Further advantageous refinements of the invention emerge from the dependent claims.

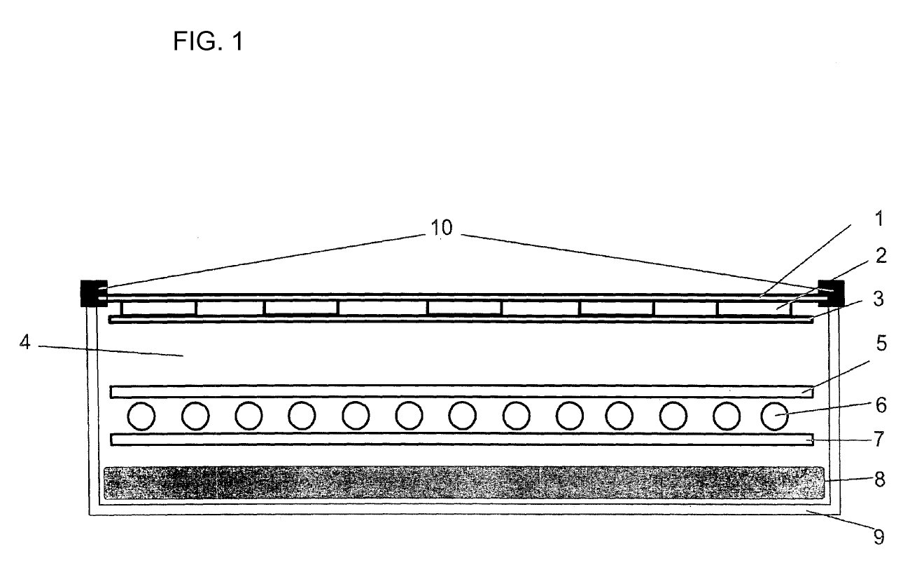

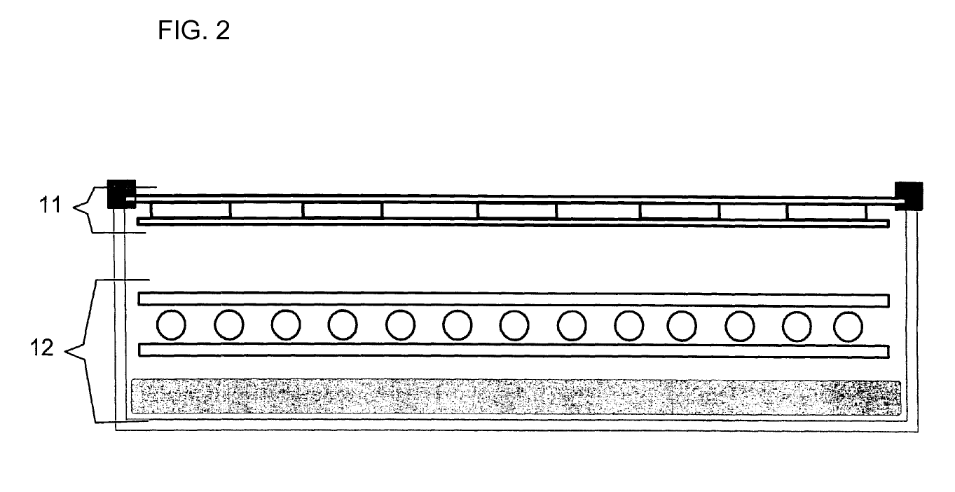

In the following text, the collector according to the invention is intended to be explained in more detail on the basis of FIGS. 1 and 2.

The collector according to the invention comprises a housing 9, which forms the base and the side walls of the collector and holds all additional components and parts of the collector, and a transparent support 1 which closes-off the collector toward the top and at the same time protects against external influences from this direction.

Alternatively, the solar thermal collector can be designed having a double-chamber profile with a vacuum or the interior of the housing as such can be evacuated.

The housing 9 and transparent support 1 are connected to each other using a seal 10 designed according to the prior art.

A semitransparent photovoltaic module 11 forms the upper part of the collector according to the invention, while the lower part of the collector corresponds to a solar thermal module 12.

Photovoltaic elements 2 are arranged on the underside and hence on the inner side of the transparent support 1, which photovoltaic elements are preferably affixed to the inner side of the transparent support 1 by means of a transparent fixing layer for PV elements 3.

In accordance with the prior art described, for example, in DE 4323270, these photovoltaic elements 2 are arranged with respect to the semitransparent hybrid collectors such that they only cover part of the irradiated surface and hence the sun can radiate into the collector.

According to the invention, an insulation space 4 is arranged below this fixing layer 3, the depth of which insulation space is designed according to the particular territorial requirements and/or was adapted to the degree of transmission of the semitransparent photovoltaic module 11.

The height of the insulation space 4 is determined by the degree of transparency. To this end, measurements have shown that it is advantageous to increase the height of the insulation space if the degree of transparency is increased because in this case the effect of the PV layer as a heat shield was detected in only a limited fashion.

If the proportion of the photovoltaics increases, the degree of transparency decreases. In this case it is advantageous to reduce the distance since the PV layer formed from radiation opaque wafers acts as a heat shield and additionally the heated photovoltaic cells transfer heat by means of heat radiation more easily to the absorber layer when the distance is reduced.

The insulation space 4 is adjoined by an absorber 5 which preferably has a coating which improves the effectiveness thereof, piping 6 for the medium carrying the heat energy, a reflection layer 7 and insulation 8 arranged below said layer.

Likewise, the reflection layer 7 can be arranged as an absorption layer and the insulation 8 obtains a reflection layer.

The photovoltaic elements 2 emit heat energy into the interior of the collector because the outer semitransparent photovoltaic component forms a heat shield preventing heat emission to the surroundings due to a higher temperature potential thereof compared to the solar thermal absorber.

Thermalization is a loss mechanism which results in extreme heating of the cells. Heating by the infrared component of the sunlight generates so-called lattice oscillations. These in turn ensure that photons not involved in the charge separation process are more likely to collide with the lattice structure. These photons having energy greater than the band gap excite the charge carriers into states which lie above the band edge. The difference between the energy of the excited state and the energy of the band edge is transferred to the crystal lattice as thermal energy.

During operation the photovoltaic component thus has a higher temperature compared to the absorber 5 and this prevents heat loss in this direction.

The insulation space 4 which prevents convective heat losses but transmits heat radiation defines the distance of the photovoltaic component to the solar thermal component which is arranged below the insulation space 4 in the installation direction.

If the height of the insulation space 4 is maximized, the electrical efficiency of the photovoltaic component is increased because less heat energy is transferred from the solar thermal absorber 5 to the semitransparent PV module 2.

If the height of the insulation space 4 is minimized, this increases the heat transfer from the solar thermal component 5 to the photovoltaic component 2 and the electrical efficiency is minimized since the operation of photovoltaic elements is lossy above standard test conditions with a cell temperature of 25° C.

Thus, selecting the height of the insulation space 4 affords the possibility of adjusting the collector according to the invention in accordance with the respective requirements.

Depending on the respective requirement, an adjustment can be effected according to the respective requirement for electrical energy and heat energy.

This is effected by selecting the distance between the solar thermal absorber 5 and the photovoltaic module 2; a further possibility for adjusting comprises selecting the degree of transparency of the photovoltaic module 2.

The possibility of no transparent fixing layer 3 should also be considered to be within the scope of protection if the photovoltaic layer 2 is attached to the transparent support 1 in a different fashion.

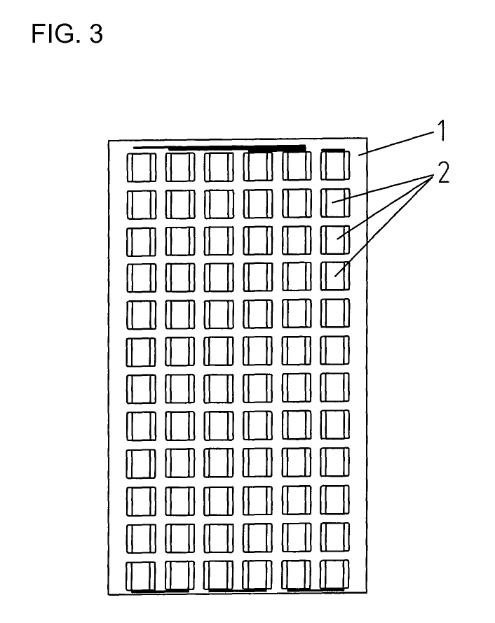

In the following text, the solution according to the invention is intended to be explained in more detail on the basis of exemplary embodiments and FIGS. 3 to 6.

One exemplary embodiment of the invention is illustrated in FIG. 3. By way of example, shown here is the case where the proportion of the total surface which is transparent is 60%.

This is achieved by the evenly distributed arrangement of silicon wafers or by extensive cutting of thin layer solar cells which are subsequently subdivided into many individual photovoltaic regions by suitable methods.

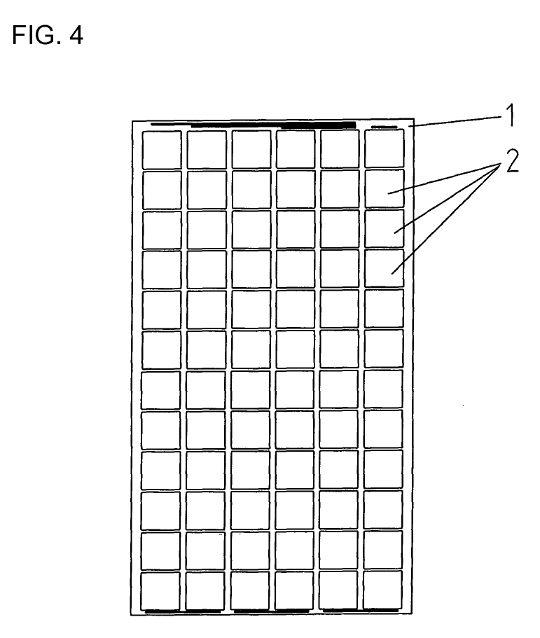

The degree of transparency can advantageously be scaled freely in the case of thin layer technology, whereas the degree of transparency when using silicon wafers is determined by the size of the wafers used. Thus, as shown in FIG. 3, the use of 5 inch wafers can achieve a degree of transparency of 60%, whereas 6 inch wafers achieve a degree of transparency of 30%, as shown in FIG. 4.

The degree of transmission can also be set by a local photovoltaic section and a transparent section. An advantageous interpretation of the solution according to the invention can for example consist of a concentrated arrangement of the photovoltaic part in part of the collector.

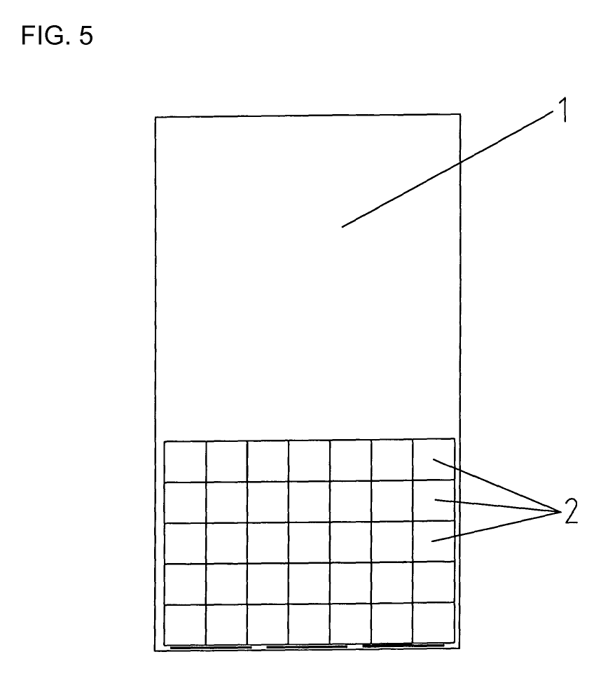

In this case it would in turn be advantageous to arrange the photovoltaic part at the bottom, as shown in FIG. 5.

Here, a positive effect would be a lower thermal load on the photovoltaic cells at rest or when little heat is removed, since a solar thermal collector develops the least amount of heat at that location due to the design thereof.

By contrast, an opposing flow can also be selected, as a result of which a different distribution of the photovoltaic elements becomes possible.

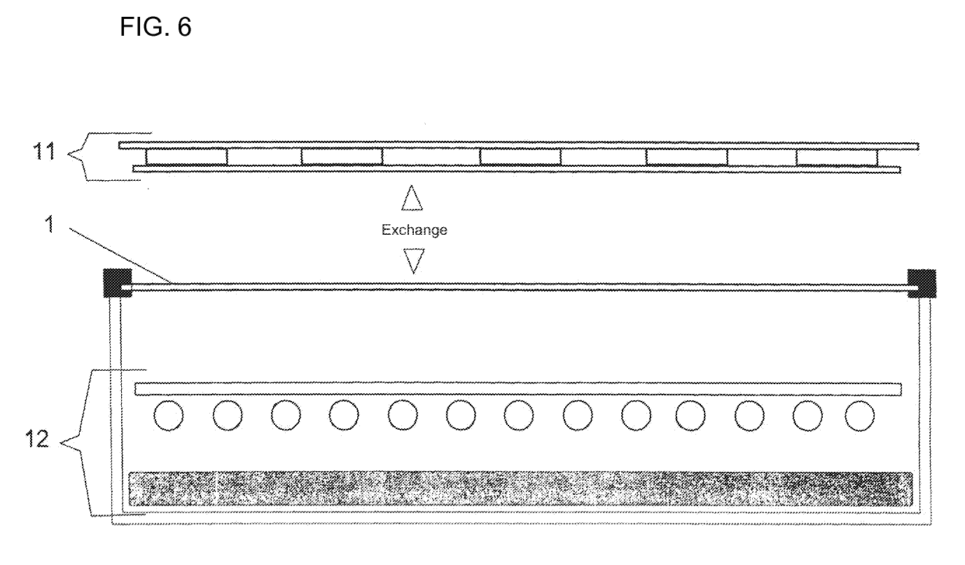

FIG. 6 shows a solar thermal collector corresponding to the prior art. It is altered by replacing the transparent layer 1 with a corresponding semitransparent photovoltaic support layer.

This affords the possibility of retrofitting already installed solar thermal collectors such that a collector in accordance with the solution according to the invention is created.

1-11. (canceled)

12. A solar collector with radiation opaque wafers for generating electrical and thermal energy exclusively from solar radiation, comprising:
a common housing;
a semitransparent photovoltaic module disposed in said common housing and forming an upper part of the solar collector;
a solar thermal module disposed in said common housing and not mechanically connected to said photovoltaic module, said solar thermal module forming a lower part of the collector;
an insulation space formed between said photovoltaic module and said solar thermal module and configured to allow heat radiation to pass while preventing convective heat loss; and
a transparent support disposed to close off the collector in a direction of the solar radiation.

13. The collector according to claim 12, wherein said photovoltaic module comprises said transparent support and photovoltaic elements disposed on an underside of said transparent support.

14. The collector according to claim 12, wherein said solar thermal module comprises an absorber, piping for heat energy carrying medium, a reflection layer, and insulation below said reflection layer.

15. The collector according to claim 12, wherein a depth of said insulation space is configured in accordance with a particular territorial requirement and specific meteorological conditions thereof.

16. The collector according to claim 12, wherein a depth of said insulation space is variable in accordance with a degree of transmission of photovoltaic elements of said photovoltaic module.

17. The collector according to claim 16, wherein the depth of said insulation space varies in accordance with the degree of transmission of said photovoltaic elements and according to particular territorial requirements and specific meteorological conditions thereof.

18. The collector according to claim 12, wherein said photovoltaic module comprises a plurality of solar cells and said solar cells are disposed at a mutual spacing distance from one another to ensure that said photovoltaic module is transparent.

19. The collector according to claim 14, wherein said absorber does not have a coating behind said solar cells of said photovoltaic element to cause a radiation energy to be absorbed by said photovoltaic element.

20. The collector according to claim 14, wherein said reflection layer is an absorption layer and said insulation is provided with a reflection layer.

21. The collector according to claim 12, wherein a transparent support of a solar thermal collector is replaced by a corresponding said semitransparent photovoltaic module.

22. The collector according to claim 12, wherein the collector is formed with a local photovoltaic section and a transparent section.
